(19) United States
(12) Patent Application Publication
(10) Pub. No.: US 2017/0156212 A1
(43) Pub. Date: Jun. 1, 2017

(54) ELECTROMAGNETIC WAVE SHIELD STRUCTURE AND ELECTRONIC DEVICE

(71) Applicant: FUJITSU LIMITED, Kawasaki-shi (JP)

(72) Inventors: Yasushi Yui, Kawasaki (JP); Shinichirou OKAMOTO, Yokohama (JP); Tadashi Katsui, Kawasaki (JP)

(73) Assignee: FUJITSU LIMITED, Kawasaki-shi (JP)

(21) Appl. No.: 15/294,829

(22) Filed: Oct. 17, 2016

(30) Foreign Application Priority Data
Nov. 30, 2015 (JP) 2015-233582

(51) Int. Cl. H05K 1/18; H05K 9/00

(52) U.S. Cl. CPC H05K 1/18; H05K 9/0081

(57) ABSTRACT

An electromagnetic wave shield structure includes: a substrate on which an electromagnetic wave emission source is mounted; a frame body provided over the substrate and including a conductor which surrounds an outer periphery of the electromagnetic wave emission source and receives a specific potential from the substrate; and a lid body, including a first insulator portion including a first surface facing the electromagnetic wave emission source and a second surface opposite to the first surface which are covered by a first conductive film electrically coupled with the frame body, configured to close an opening end of the frame body.

### CROSS-REFERENCE TO RELATED APPLICATION

This application is based upon and claims the benefit of priority of the prior Japanese Patent Application No. 2015-233582, filed on Nov. 30, 2015, the entire contents of which are incorporated herein by reference.

### FIELD

The embodiment discussed herein is related to an electromagnetic wave shield structure and an electronic device.

### BACKGROUND

Electromagnetic waves emitted from an electromagnetic wave emission source such as a high frequency semiconductor are shielded.

A related technique is disclosed in Japanese Laid-open Patent Publication No. 2002-134987 or Japanese Laid-open Patent Publication No. 2010-165867.

### SUMMARY

According to an aspect of the embodiments, an electromagnetic wave shield structure includes: a substrate on which an electromagnetic wave emission source is mounted; a frame body provided over the substrate and including a conductor which surrounds an outer periphery of the electromagnetic wave emission source and receives a specific potential from the substrate; and a lid body, including a first insulator portion including a first surface facing the electromagnetic wave emission source and a second surface opposite to the first surface which are covered by a first conductive film electrically coupled with the frame body, configured to close an opening end of the frame body.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a sectional view of an electronic device including an electromagnetic wave shield structure;

FIG. 2 illustrates an example of an exploded perspective view of a component of an electronic device;

FIGS. 3A to 3C illustrate an example of a perspective view of an electromagnetic wave shield structure;

FIGS. 4A to 4E illustrate an example of a manufacturing method of an electromagnetic wave shield structure;

FIG. 5 illustrates an example of results which are obtained by measuring shielding performance, with respect to an electromagnetic wave, of a test piece corresponding to a structure of a base portion of a lid body and a test piece composed of a single-layer metal plate;

FIGS. 6A to 6D illustrate an example of a sectional view of the lid body;

FIG. 7 illustrates an example of a sectional view of an electronic device including an electromagnetic wave shield structure;

FIG. 8 illustrates an example of a sectional view of an electronic device including an electromagnetic wave shield structure;

FIG. 9 illustrates an example of a sectional view of an electronic device including an electromagnetic wave shield structure; and

FIG. 10 illustrates an example of a sectional view of an electronic device including an electromagnetic wave shield structure.

### DESCRIPTION OF EMBODIMENT

A packaged microwave device includes a plurality of electronic components which are attached to a surface of a base and a cover which is attached to the surface of the base and of which the whole of an outer surface and a part of an inner surface are made of a plated electromagnetic wave absorbable thermoplastic material, for example.

A board enclosing instrument is composed of a frame structure which houses and fixes an electronic circuit board therein and a board enclosing cloth which is made of a conductive woven fabric, which is made by metal-plating a resin woven fabric, and covers the electronic circuit board in a manner to be held by the frame structure, for example.

In order to shield a high-frequency electromagnetic wave emitted from an electromagnetic wave emission source such as a high frequency semiconductor device which is mounted on a wiring substrate, the electromagnetic wave emission source is covered by a structure which is obtained by molding a metal plate in a box shape, for example. However, if a frequency of an electromagnetic wave emitted from a high frequency semiconductor device is further increased along with improvement of performance of the high frequency semiconductor device (for example, 100 MHz or higher) in the future, it may become difficult to sufficiently shield an electromagnetic wave by a structure having the simple configuration as that described above.

In the drawings, identical or equivalent constituent elements and portions may be given identical reference characters and duplicate description may be omitted.

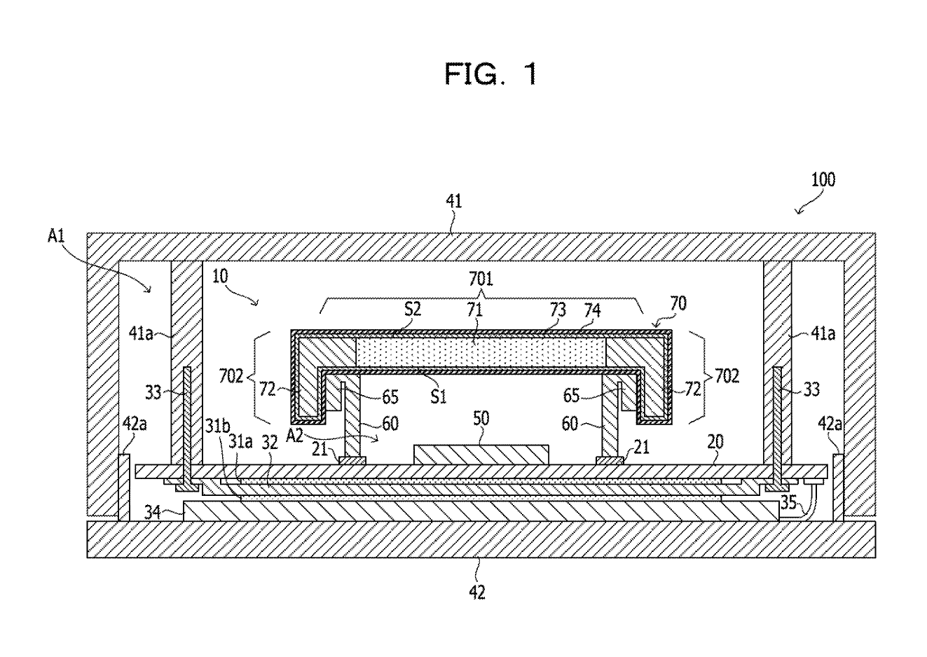

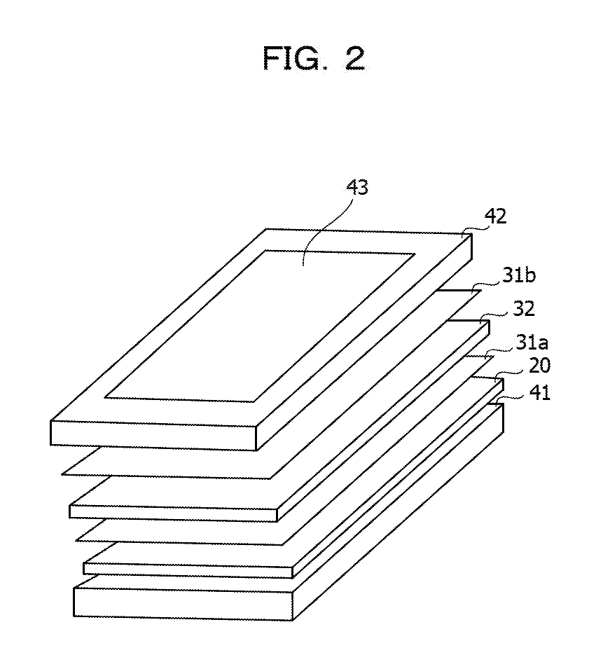

FIG. 1 illustrates an example of a sectional view of an electronic device including an electromagnetic wave shield structure. FIG. 2 illustrates an example of an exploded perspective view of a component of an electronic device.

An electronic device 100 may be a tablet type computer, for example. In a housing space Al which is formed between a front surface case 42 and a back surface case 41, a wiring substrate 20 and a liquid crystal unit 34 are disposed.

The front surface case 42 is bonded with the back surface case 41 at bonding portions 42a, which are protruded in the housing space A1, on both end portions of the front surface case 42. On the center of the front surface case 42, an opening portion 43 (refer to FIG. 2) from which a display surface of the liquid crystal unit 34 is exposed is formed. In FIG. 2, the liquid crystal unit 34 is housed in the front surface case 42.

Between the liquid crystal unit 34 and the wiring substrate 20, a reinforcing sheet metal 32 is provided. One surface of the reinforcing sheet metal 32 is bonded to a surface, which is on a side opposite to the display surface, of the liquid crystal unit 34 with a double sided tape 31b. The other surface of the reinforcing sheet metal 32 is bonded to a surface, which is on a side facing the front surface case 42, of the wiring substrate 20 with a double sided tape 31a.

A video signal outputted from the wiring substrate 20 is supplied to the liquid crystal unit 34 via a flexible cable 35. On the display surface of the liquid crystal unit 34, a display content corresponding to a video signal which is supplied via the flexible cable 35 is displayed.

The back surface case 41 includes a supporting portion 41a which extends inside the housing space A1. The wiring substrate 20 is fixed to the supporting portion 41a together with the reinforcing sheet metal 32 by screws 33.

On a surface, which faces the back surface case 41, of the wiring substrate 20, a semiconductor device 50 is mounted. The semiconductor device 50 may be a calculation device such as a central processing unit (CPU) and a micro processing unit (MPU) or an image processing device and may correspond to an electromagnetic wave emission source which emits a high frequency electromagnetic wave (100 MHz or higher, for example).

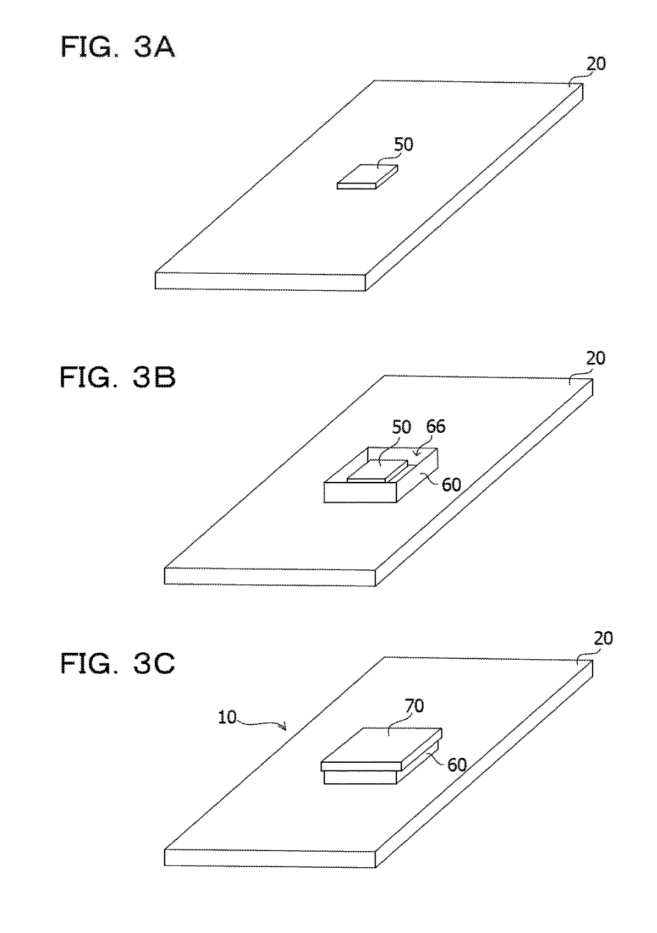

The electronic device 100 includes an electromagnetic wave shield structure 10 which shields an electromagnetic wave emitted from the semiconductor device 50. FIG. 3A, FIG. 3B, and FIG. 3C illustrate an example of a perspective view of the electromagnetic wave shield structure. The electromagnetic wave shield structure 10 includes the wiring substrate 20, a frame body 60, and a lid body 70.

FIG. 3A illustrates the semiconductor device 50 which is mounted on the wiring substrate 20 and is the electromagnetic wave emission source. The frame body 60 is a frame-shaped structural part which is provided on the wiring substrate 20 and includes a conductor surrounding an outer periphery of the semiconductor device 50 as illustrated in FIG. 3B. The frame body 60 is higher than the semiconductor device 50 and covers sides of the semiconductor device 50 in a manner to form an opening end 66 above the semiconductor device 50. The frame body 60 forms a frame having a rectangular shape four sides of which are arranged in parallel with respective sides of the semiconductor device 50 which has a rectangular shape. The semiconductor device 50 is disposed inside the frame body 60. As a conductor constituting the frame body 60, copper, nickel, iron, cobalt, tin, zinc, chromium, silver, gold, platinum, aluminum, titanium, magnesium, indium, carbon, boron, or an alloy containing these substances (stainless, for example) may be used.

As illustrated in FIG. 1, the frame body 60 includes a spring portion 65 which is formed by folding an upper end portion of the frame body 60 by 180 degrees to the outside. The spring portion 65 may be used for attaching the lid body 70. The frame body 60 is electrically connected with an electrode pad 21 formed on the surface of the wiring substrate 20 and is supplied with a predetermined potential (ground potential, for example) via the electrode pads 21. Accordingly, the frame body 60 is fixed at the predetermined potential.

The lid body 70 is attached to the frame body 60 so as to close the opening end 66 of the frame body 60, as illustrated in FIG. 3C. For example, the lid body 70 covers above the semiconductor device 50. The semiconductor device 50 is housed in a shielded space A2 (refer to FIG. 1) which is surrounded by the frame body 60 and the lid body 70.

As illustrated in FIG. 1, the lid body 70 has a box shape which includes a base portion 701 which covers above the semiconductor device 50 and extends in a direction parallel to a main surface of the wiring substrate 20 and a lateral wall portion 702 which orthogonally extends from an end portion of the base portion 701 toward the wiring substrate 20. The lid body 70 is attached to the frame body 60 such that the lateral wall portion 702 is abutted on the spring portion 65 formed on the upper end portion of the frame body 60. The lid body 70 is brought into close contact with the frame body 60 by biasing force, which is supplied from the spring portion 65 and acts toward the outside of the frame body 60, and accordingly, is not easily dropped off from the frame body 60.

The lid body 70 is composed of a hybrid material including an insulator portion 71 and a metal portion 72. The insulator portion 71 is disposed on a portion which closes the opening end 66 of the frame body 60 such as a portion which covers above the semiconductor device 50. The major part of the base portion 701 of the lid body 70 is composed of the insulator portion 71, for example. As a material of the insulator portion 71, a resin material such as ABS resin, polycarbonate (PC), polyamide (PA), polyethylene terephthalate (PET), polyphenylene sulfide (PPS), polyether sulfone (PES), liquid crystal polymer (LCP), polyether imide (PEI), and fluorine resin (PFA) or a composite material in which a fiber material (such as glass fiber, carbon fiber, and aramid fiber) is incorporated into these resin materials in a rate of 70 wt % or lower may be used. When the insulator portion 71 is made of resin, processing may become easier than the case where the insulator portion 71 is made of other materials. As a material of the insulator portion 71, rubber, elastomer, glass, a natural ore, a paper, or a cloth may be used.

The metal portion 72 is disposed on a portion abutted on the frame body 60. For example, the lateral wall portion 702 of the lid body 70 includes the metal portion 72. As a material of the metal portion 72, copper, nickel, iron, cobalt, tin, zinc, chromium, silver, gold, platinum, aluminum, titanium, magnesium, indium, carbon, boron, or an alloy containing these substances may be used.

The insulator portion 71 and the metal portion 72 may be integrated by integral molding or bonding. The whole surface of the insulator portion 71 and the metal portion 72 is covered by conductive films 73 and 74 which constitute a double layer. For example, a first surface S1, which faces the semiconductor device 50, (inside the shielded space A2) and a second surface S2, which is on a side opposite to the first surface S1, (outside the shielded space A2) of the insulator portion 71 are covered by the conductive films 73 and 74. The whole surface of the metal portion 72 including a portion which is brought into contact with the frame body 60 is covered by the conductive films 73 and 74.

The conductive films 73 and 74 may be formed on the surfaces of the insulator portion 71 and the metal portion 72 by the plating method or the vapor deposition method, for example. As a material of the conductive films 73 and 74, copper, nickel, iron, cobalt, tin, zinc, chromium, silver, gold, platinum, aluminum, titanium, magnesium, indium, carbon, boron, or an alloy containing these substances may be used. For example, the double-layer conductive film may be formed on the surfaces of the insulator portion 71 and the metal portion 72 and a conductive film of at least single layer may be formed on the surfaces of the insulator portion 71 and the metal portion 72. In the case of the double-layer conductive film, a material having relatively-high conductivity (copper, for example) is selected for the conductive film 73 which is the lower layer and a material which is capable of protecting the conductive film 73 which is the lower layer from corrosion (nickel, for example) may be selected for the conductive film 74 which is the upper layer.

The metal portion 72 (the lateral wall portion 702), which is covered by the conductive films 73 and 74, of the lid body 70 is brought into contact with the frame body 60 and accordingly, a predetermined potential is applied to the conductive films 73 and 74 and the metal portion 72 via the frame body 60 and the electrode pad 21 of the wiring substrate 20. Accordingly, the whole surface of the lid body 70 including the first surface S1 and the second surface S2 of the insulator portion 71 is fixed on a potential same as that of the frame body 60.

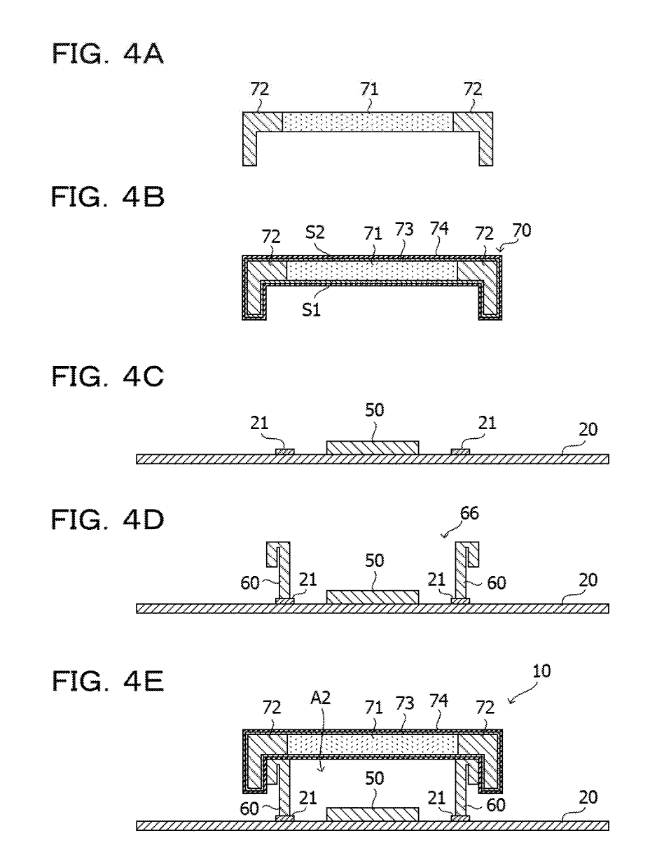

FIGS. 4A to 4E illustrate an example of a manufacturing method of an electromagnetic wave shield structure.

For example, the insulator portion 71 and the metal portion 72 which have the thickness of 1 mm or smaller are integrated by integral molding or bonding so as to mold a form of the lid body 70 (FIG. 4A). As a material of the insulator portion 71, polyphenylene sulfide (PPS) which contains 40 wt % of glass fiber may be used, for example. As a material of the metal portion 72, aluminum may be used, for example.

The conductive films 73 and 74 which have the thickness of 1 μm or larger are formed on the whole surface of the insulator portion 71 and the metal portion 72 by the plating method or the vapor deposition method. The first surface S1 and the second surface S2 of the insulator portion 71 are covered by the conductive films 73 and 74 (FIG. 4B). Copper may be used for the conductive film 73 which is the lower layer, for example. Nickel may be used for the conductive film 74 which is the upper layer, for example.

The semiconductor device 50 which serves as an electromagnetic wave emission source is mounted on the wiring substrate 20. On the surface of the wiring substrate 20, the electrode pads 21 to which a predetermined potential (ground potential, for example) is applied are provided on positions sandwiching the semiconductor device 50 (FIG. 4C).

The frame body 60 which surrounds the outer periphery of the semiconductor device 50 is mounted on the wiring substrate 20. The frame body 60 covers the sides of the semiconductor device 50 in a manner to form the opening end 66 above the semiconductor device 50. The frame body 60 is electrically and mechanically connected with the electrode pads 21, which are formed on the surface of the wiring substrate 20, by soldering, for example. Accordingly, the frame body 60 is supplied with a predetermined potential (ground potential, for example) via the electrode pads 21 and the potential of the frame body 60 is fixed (FIG. 4D). As a material of the frame body 60, stainless may be used, for example.

The lid body 70 is attached to the frame body 60 so as to close the opening end 66 of the frame body 60. The metal portion 72, which is covered by the conductive films 73 and 74, of the lid body 70 is abutted on the frame body 60, accordingly a predetermined potential is applied to the conductive films 73 and 74 and the metal portion 72, and the potential of the whole surface of the lid body 70 is fixed on the potential same as that of the frame body 60. The semiconductor device 50 is housed in the shielded space A2 which is surrounded by the frame body 60 and the lid body 70 (FIG. 4E).

In the electromagnetic wave shield structure 10 and the electronic device 100, both of the first surface S1 and the second surface S2 of the insulator portion 71 included in the base portion 701 of the lid body 70 are covered by the conductive films 73 and 74. For example, a capacitor structure obtained by sandwiching an insulator by conductive films is formed in the lid body 70. Therefore, a double-layer electromagnetic wave shielding wall is formed on an emission path of an electromagnetic wave emitted from the semiconductor device 50. For example, the first electromagnetic wave shielding wall is formed by the conductive films 73 and 74 which cover the first surface S1 of the insulator portion 71 and the second electromagnetic wave shielding wall is formed by the conductive films 73 and 74 which cover the second surface S2 of the insulator portion 71. Thus, a plurality of electromagnetic wave shielding walls which are layered with the insulator interposed therebetween are formed on an emission path of an electromagnetic wave, so that an area of the electromagnetic wave shielding wall is increased compared to the case where an electromagnetic wave shielding wall is formed by a single-layer metal plate. Accordingly, shielding performance with respect to an electromagnetic wave emitted from the semiconductor device 50 may be improved.

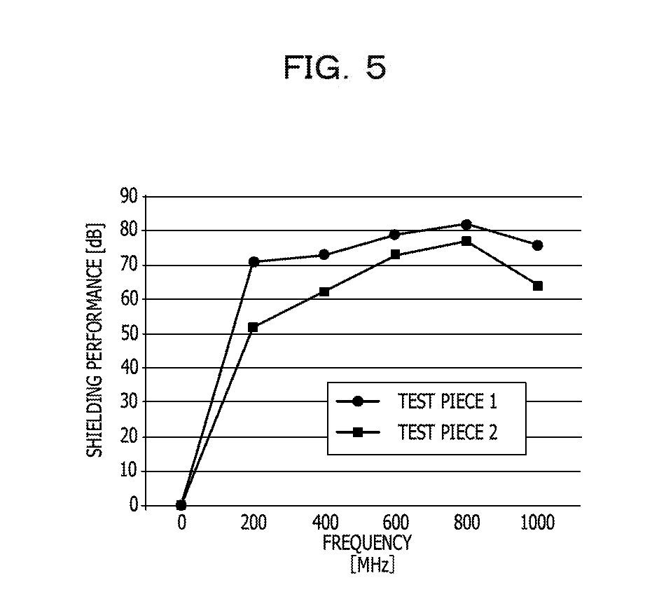

FIG. 5 illustrates an example of results which are obtained by measuring shielding performance, with respect to an electromagnetic wave, of a test piece corresponding to a structure of the base portion of the lid body and a test piece composed of a single-layer metal plate. FIG. 5 illustrates a graph of results obtained by measuring shielding performance, with respect to an electromagnetic wave, of a test piece 1 simulating the structure of the base portion 701 of the lid body 70 and a test piece 2 composed of a single-layer metal plate by the advantest method. In the advantest method, an electromagnetic wave having a specific frequency is generated in a shielded box, an electromagnetic wave which passes through the test piece are received, and attenuation of the electromagnetic wave caused by the passing through the test piece is measured so as to measure shielding performance of the test piece with respect to an electromagnetic wave.

As the test piece 1, a plate material which is obtained by coating both surfaces of polyphenylene sulfide (PPS) having the thickness of approximately 1 mm by a copper plated film having the thickness of approximately 1 μm and a nickel plated film having the thickness of approximately 0.2 μm is used. As the test piece 2, a stainless plate having the thickness of approximately 1 mm is used. Both of the test piece 1 and the test piece 2 have the size of 200 mm×200 mm.

The horizontal axis of the graph illustrated in FIG. 5 represents a frequency of an electromagnetic wave and the vertical axis represents shielding performance of the test piece. Shielding performance P is expressed by formula (1) below.

P=−20log(X1/X2) [dB] (1)

X1 denotes the intensity of an electromagnetic wave measured at a reception side in the case where the electromagnetic wave is shielded by the test piece. X2 denotes the intensity of an electromagnetic wave measured at the reception side in the case where the electromagnetic wave is not shielded by the test piece. A larger value of the shielding performance P represents higher shielding capability with respect to an electromagnetic wave.

As illustrated in FIG. 5, in the whole measured frequency range, the test piece 1 simulating the structure of the base portion 701 of the lid body 70 exhibits higher shielding performance than the test piece 2 which is composed of the single-layer metal plate. For example, when the electromagnetic wave emission source is covered by the lid body 70 including the insulator portion 71 both surfaces of which are covered by the conductive films 73 and 74, higher shielding performance is obtained compared to the case where the electromagnetic wave emission source is covered by the single-layer metal plate.

In the lid body 70, the lateral wall portion 702 which is abutted on the frame body 60 includes the metal portion 72 having higher strength than the insulator portion 71, so that a risk of damage of the lateral wall portion 702 caused by contact with the frame body 60 may be reduced. Thus, the lid body 70 includes the hybrid material including the insulator portion 71 and the metal portion 72, so that shielding performance with respect to an electromagnetic wave and mechanical strength may be compatible.

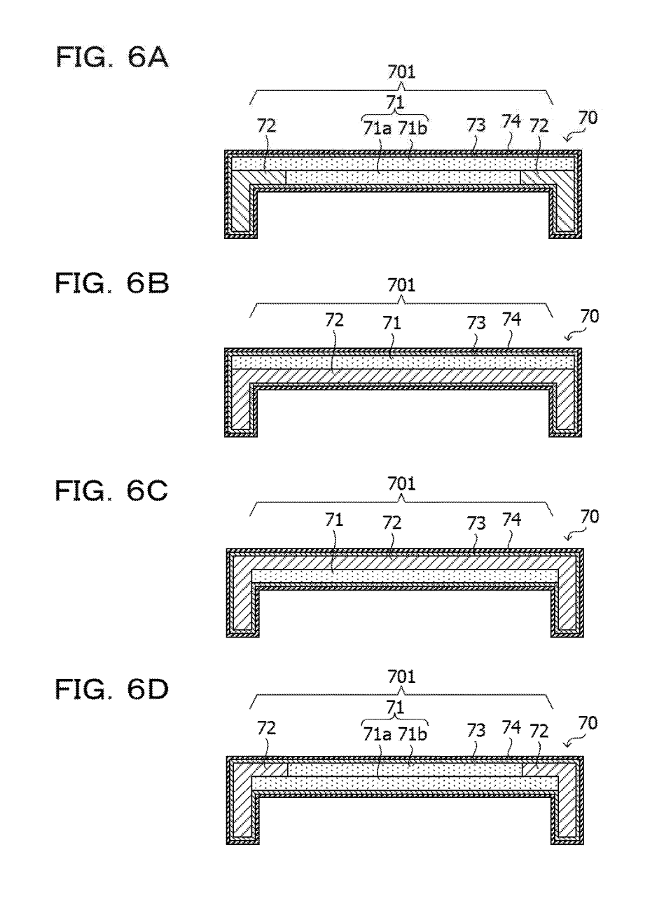

FIGS. 6A to 6D illustrate an example of a sectional view of the lid body. The insulator portion 71 and the metal portion 72 of the lid body 70 may be configured as illustrated in FIGS. 6A to 6D, for example. As illustrated in FIG. 6A and FIG. 6D, the base portion 701 of the lid body 70 may include the insulator portion 71, which includes insulator layers 71a and 71b which constitute a double layer, for example. As illustrated in FIG. 6B and FIG. 6C, the base portion 701 of the lid body 70 may include a lamination of the insulator portion 71 and the metal portion 72. In any of FIGS. 6A to 6D, the double-layer electromagnetic wave shielding wall is formed on an emission path of an electromagnetic wave emitted from the semiconductor device 50, so that high shielding performance may be obtained. For example, the electromagnetic wave emission source may be the semiconductor device 50 and the electromagnetic wave emission source may be a resistive element, a passive element such as a coil, or other electronic components.

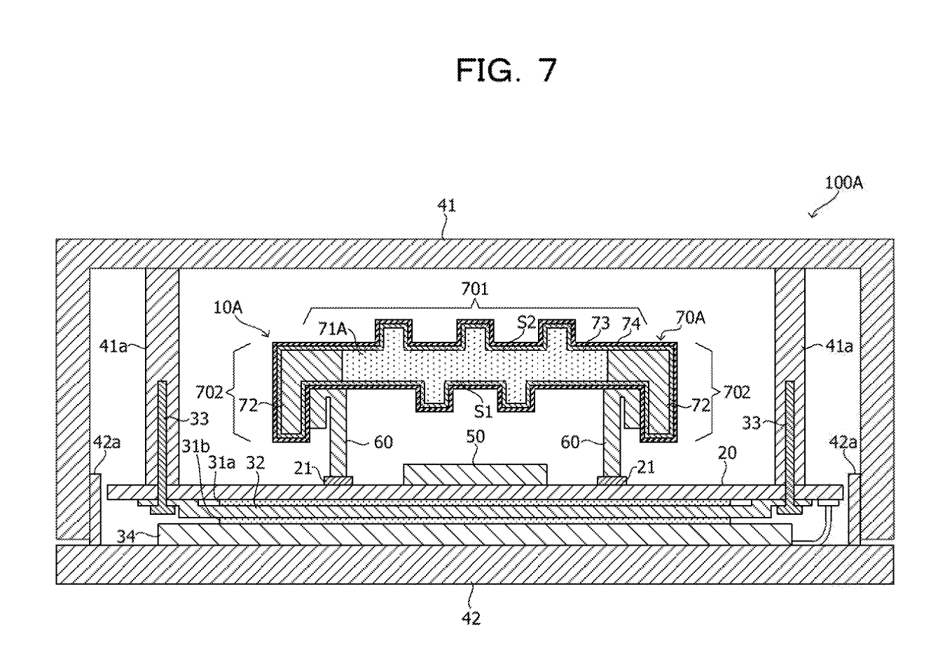

FIG. 7 illustrates an example of a sectional view of an electronic device including an electromagnetic wave shield structure. In an electromagnetic wave shield structure 10A, the first surface S1 and the second surface S2 of an insulator portion 71A included in the base portion 701 of a lid body 70A are uneven surfaces. The conductive films 73 and 74 are provided along the unevenness formed on the first surface S1 and the second surface S2 of the insulator portion 71A.

In the electromagnetic wave shield structure 10A, a double-layer electromagnetic wave shielding wall is formed on an emission path of an electromagnetic wave emitted from the semiconductor device 50, as is the case with FIG. 1. The conductive films 73 and 74 are formed along the unevenness formed on the first surface S1 and the second surface S2 of the insulator portion 71A, so that an area of the electromagnetic wave shielding wall is increased and accordingly, shielding performance with respect to an electromagnetic wave may be further improved.

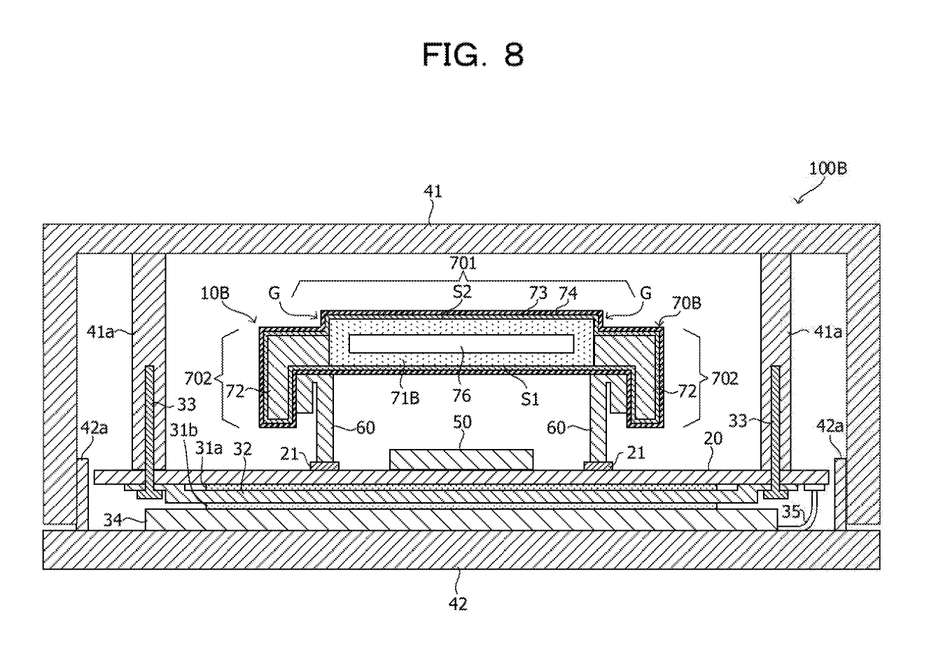

FIG. 8 illustrates an example of a sectional view of an electronic device including an electromagnetic wave shield structure. In an electromagnetic wave shield structure 10B, a cavity portion 76 is formed in the inside of an insulator portion 71B included in the base portion 701 of a lid body 70B. For example, the insulator portion 71B has a hollow structure. Thus, the cavity portion 76 is formed in the inside of the insulator portion 71B, so that the thickness of the insulator portion 71B may be increased. The conductive films 73 and 74 which cover the first surface S1 and the second surface S2 of the insulator portion 71 cover a step portion G which is formed on a bonding portion between the insulator portion 71B and the metal portion 72, as well.

In the electromagnetic wave shield structure 10B, a double-layer electromagnetic wave shielding wall is formed on an emission path of an electromagnetic wave emitted from the semiconductor device 50, as is the case with FIG. 1. The insulator portion 71B is configured to have the hollow structure to increase the thickness of the insulator portion 71B, so that areas of the conductive films 73 and 74 may be increased. The area of the electromagnetic wave shielding wall is increased, so that shielding performance with respect to an electromagnetic wave may be further improved.

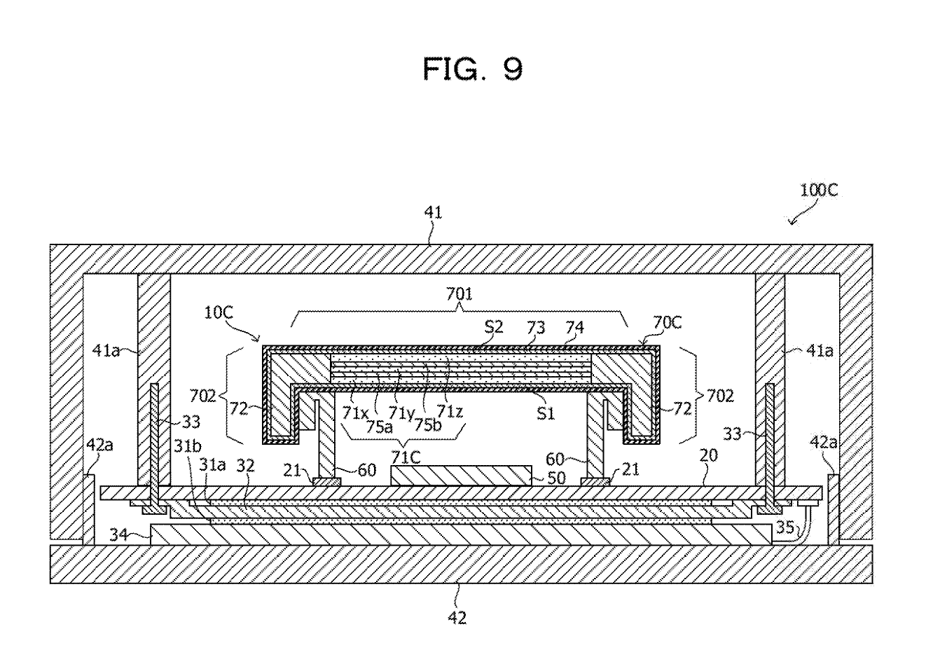

FIG. 9 illustrates an example of a sectional view of an electronic device including an electromagnetic wave shield structure. In an electromagnetic wave shield structure 10C, an insulator portion 71C included in the base portion 701 of a lid body 70C includes a laminated body in which insulator layers and conductor layers are alternately laminated. For example, in the insulator portion 71C, a first conductor layer 75a is provided between a first insulator layer 71x and a second insulator layer 71y. For example, a second conductor layer 75b is provided between the second insulator layer 71y and a third insulator layer 71z. The conductive films 73 and 74 cover the first surface S1 and the second surface S2 of the laminated body including the insulator layers 71x, 71y, and 71z and the conductor layers 75a and 75b.

In the electromagnetic wave shield structure 10C, the number of layers of an electromagnetic wave shielding wall which is formed on an emission path of an electromagnetic wave emitted from the semiconductor device 50 is four. For example, the first electromagnetic wave shielding wall is formed of the conductive films 73 and 74 which cover the first surface S1 of the laminated body and the second electromagnetic wave shielding wall is formed of the first conductor layer 75a. The third electromagnetic wave shielding wall is formed of the second conductor layer 75b and the fourth electromagnetic wave shielding wall is formed of the conductive films 73 and 74 which cover the second surface S2 of the laminated body. Thus, the number of layers of the electromagnetic wave shielding wall which is formed on an emission path of an electromagnetic wave emitted from the semiconductor device 50 is four, so that shielding performance with respect to an electromagnetic wave may be further improved. For example, the numbers of layers of the insulator layers and the conductor layers included in the insulator portion 71C of the lid body 70 may be increased or decreased as appropriate.

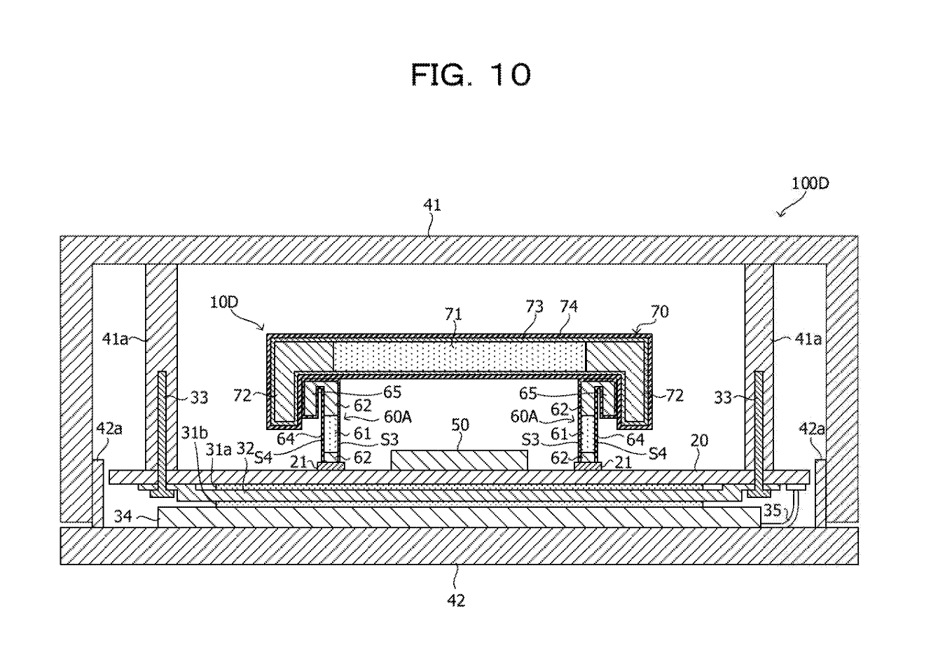

FIG. 10 illustrates an example of a sectional view of an electronic device including an electromagnetic wave shield structure. In an electromagnetic wave shield structure 10D, a frame body 60A is composed of a hybrid material including an insulator portion 61 and a metal portion 62 as is the case with the lid body 70. The metal portion 62 is disposed on an upper end, on which the spring portion 65 on which the lid body 70 is abutted is formed, of the frame body 60A and a lower end, which is bonded with the electrode pad 21, of the frame body 60A. The insulator portion 61 is disposed on the center in the height direction of the frame body 60A. For the insulator portion 61 and the metal portion 62, materials same as the candidate materials of the insulator portion 71 and the metal portion 72 included in the lid body 70 may be used. The whole surfaces of the insulator portion 61 and the metal portion 62 are covered by a conductive film 64. For example, as for the insulator portion 61, an inner lateral surface S3 and an outer lateral surface S4 of the frame body 60A are covered by the conductive film 64. To the conductive film 64, a predetermined potential (ground potential, for example) is supplied via the electrode pad 21. For the conductive film 64, materials same as the candidate materials of the conductive films 73 and 74 included in the lid body 70 may be used. For example, the number of layers of the conductive film which covers the surface of the frame body 60A may be two or more.

In the electromagnetic wave shield structure 10D, a capacitor structure in which an insulator is sandwiched by conductive films is formed in the frame body 60A. Therefore, a double-layer electromagnetic wave shielding wall is formed on an emission path of an electromagnetic wave emitted toward the side of the semiconductor device 50. For example, the first electromagnetic wave shielding wall is formed of the conductive film 64 which covers the inner lateral surface S3 of the insulator portion 61. For example, the second electromagnetic wave shielding wall is formed of the conductive film 64 which covers the outer lateral surface S4 of the insulator portion 61. In the electromagnetic wave shield structure 10D, an electromagnetic wave emitted to the upper part of the semiconductor device 50 is shielded by a double-layer electromagnetic wave shielding wall which is formed by the lid body 70. An electromagnetic wave emitted toward the side of the semiconductor device 50 is shielded by a double-layer electromagnetic wave shielding wall which is formed by the frame body 60A. Thus, the insulator, both surfaces of which are covered by the conductive films which are fixed on a predetermined potential, covers the upper part and the side of the electromagnetic wave emission source, so that shielding performance with respect to an electromagnetic wave may be further improved.

In the frame body 60A, the spring portion 65 abutted on the lid body 70 includes the metal portion 62 having higher strength than the insulator portion 61. Therefore, a risk of damage of the spring portion 65 caused by contact with the lid body 70 may be reduced. In the frame body 60A, the bonding portion with respect to the electrode pad 21 is composed of the metal portion 62, so that a high-temperature process such as solder bonding may be used for bonding between the frame body 60A and the wiring substrate 20.

The electromagnetic wave shield structures 10, 10A, 10B, 10C, and 10D may be examples of an electromagnetic wave shield structure. The electronic devices 100, 100A, 100B, 100C, and 100D may be examples of an electronic device. The semiconductor device 50 may be an example of an electromagnetic wave emission source. The wiring substrate 20 may be an example of a substrate. The frame bodies 60 and 60A may be examples of a frame body. The lid bodies 70, 70A, 70B, and 70C may be examples of a lid body. The insulator portions 71, 71A, 71B, and 71C may be examples of an insulator portion. The conductive films 73 and 74 may be examples of a conductive film.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electromagnetic wave shield structure comprising:
a substrate on which an electromagnetic wave emission source is mounted;
a frame body provided over the substrate and including a conductor which surrounds an outer periphery of the electromagnetic wave emission source and receives a specific potential from the substrate; and
a lid body, including a first insulator portion including a first surface facing the electromagnetic wave emission source and a second surface opposite to the first surface which are covered by a first conductive film electrically coupled with the frame body, configured to close an opening end of the frame body.

2. The electromagnetic wave shield structure according to claim 1, wherein the lid body includes a metal portion which is abutted on the frame body.

3. The electromagnetic wave shield structure according to claim 1, wherein
the first surface and the second surface have unevenness, and
the first conductive film is provided along the unevenness.

4. The electromagnetic wave shield structure according to claim 1, wherein the insulator portion includes a hollow structure having a cavity portion.

5. The electromagnetic wave shield structure according to claim 1, wherein the insulator portion includes a laminated body in which insulator layers and conductive layers are alternately laminated.

6. The electromagnetic wave shield structure according to claim 1, wherein the frame body includes a second insulator portion where an inner lateral surface and an outer lateral surface of the frame body are covered by a second conductive film to which the specific potential is supplied.

7. The electromagnetic wave shield structure according to claim 1, wherein the first insulator portion contains resin.

8. The electromagnetic wave shield structure according to claim 1, wherein the frame body is bonded to an electrode pad which is formed on the substrate and to which the specific potential is supplied.

9. An electronic device comprising:
a substrate on which a semiconductor device is mounted;
a frame body provided over the substrate and including a conductor which surrounds an outer periphery of the semiconductor device and receives a specific potential from the substrate; and
a lid body, including a first insulator portion including a first surface facing the electromagnetic wave emission source and a second surface opposite to the first surface which are covered by a first conductive film electrically coupled with the frame body, configured to close an opening end of the frame body.

10. The electronic device according to claim 9, wherein the lid body includes a metal portion which is abutted on the frame body.

11. The electronic device according to claim 9, wherein
the first surface and the second surface have unevenness, and
the first conductive film is provided along the unevenness.

12. The electronic device according to claim 9, wherein the insulator portion includes a hollow structure having a cavity portion.

13. The electronic device according to claim 9, wherein the insulator portion includes a laminated body in which insulator layers and conductive layers are alternately laminated.

14. The electronic device according to claim 9, wherein the frame body includes a second insulator portion where an inner lateral surface and an outer lateral surface of the frame body are covered by a second conductive film to which the specific potential is supplied.

15. The electronic device according to claim 9, wherein the first insulator portion contains resin.

16. The electronic device according to claim 9, wherein the frame body is bonded to an electrode pad which is formed on the substrate and to which the specific potential is supplied.
